(19) United States
(12) Patent Application Publication
(10) Pub. No.: US 2014/0000705 A1
(43) Pub. Date: Jan. 2, 2014

(54) REFLECTOR SYSTEM FOR CONCENTRATING SOLAR SYSTEMS

(71) Applicants: Amine Berrada Sounni, Berkeley, CA (US); Charles Almy, Berkeley, CA (US)

(72) Inventors: Amine Berrada Sounni, Berkeley, CA (US); Charles Almy, Berkeley, CA (US)

(73) Assignee: SunPower Corporation, San Jose, CA (US)

(21) Appl. No.: 13/539,162

(22) Filed: Jun. 29, 2012

(51) Int. Cl. H01L 31/0232

(52) U.S. Cl. 136/259

(57) ABSTRACT

A solar concentrator assembly is disclosed. The solar concentrator assembly comprises a first reflective member, a second reflective member, a photovoltaic receiver comprising at least one photovoltaic solar cell unit, and a support structure coupled to the first and second reflective members and the photovoltaic receiver. The first reflective member is shaped to concentrate sunlight in front of the first reflective member, and has an edge region extending inward from an edge adjacent the second reflective member. The edge region is formed in a shape which curves away from the photovoltaic receiver near the first edge.

### TECHNICAL FIELD

Embodiments of the subject matter described herein relate generally to solar concentrating systems. More particularly, embodiments of the subject matter relate to reflector design for solar concentrating systems.

### BACKGROUND

Concentrating photovoltaic (CPV) solar energy systems have mirrors or other reflective surfaces which focus sunlight on photovoltaic receivers. CPV systems have relatively high efficiency and, depending on the photovoltaic solar cell used for the receiver, can have a higher conversion efficiency than a system which uses the same solar cell without concentrated sunlight. Conversion efficiency is a measure of the efficacy of the solar cell in converting sunlight impinging on it into electrical current.

To maintain its high efficiency, CPV systems have little margin for error in many of the sources of misalignment that can affect energy generation. For example, the pointing accuracy of the CPV system, which describes the accuracy in positioning the CPV system to reflect and concentrate sunlight on the photovoltaic receiver, should have as little error as possible, typically less than a single degree of deviation. Other sources of error or inefficiency in conversion can affect the output of the system.

CPV systems can have rows of reflector segments concentrating sunlight on rows of receiver segments. The spacing between the segments, whether reflector or receiver, is typically aligned such that the space between reflector segments corresponds to the space between receiver segments. CPV systems with rows of segmented reflectors and receivers can be one-axis trackers to follow the sun, although some track on two axes. One axis tracking CPV systems can encounter a reduction in conversion efficiency caused by the gap between reflector segments appearing on a photovoltaic receiver as an unlit area of the receiver.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a side view of an embodiment of a solar concentrator system;

FIG. 2 is a detailed side view of the embodiment of FIG. 1;

FIG. 3 is a perspective view of the embodiment of FIG. 1;

FIG. 4 is a detailed front view of an embodiment of a photovoltaic receiver used in a solar concentrator system;

FIG. 5 is a detailed front perspective of an embodiment of reflector elements used in a solar concentrator system;

FIG. 6 is a detailed rear top view of an embodiment of a solar concentrator system receiving and reflecting sunlight in one condition;

FIG. 7 is a detailed rear perspective view of an embodiment of a solar concentrator system being irradiated in another condition;

FIG. 8 is a detailed front view of an embodiment of a photovoltaic receiver receiving sunlight in the solar concentrator embodiment and in the condition of FIG. 7;

FIG. 9 is a detailed top view of the travel of light in the embodiment of a solar concentrator system of FIG. 7;

FIG. 10 is a detailed view of a photovoltaic cell unit in first and second irradiance conditions;

FIG. 11 is a top view of an embodiment of a solar concentrator system being irradiated;

FIG. 12 is a detailed top view of the embodiment of FIG. 11;

FIG. 13 is a detailed view of an edge of an embodiment of a reflective member;

FIG. 14 is a detailed view of an edge of another embodiment of a reflective member;

FIG. 15 is a side perspective view of a portion of an embodiment of a reflective member; and

FIG. 16 is a detailed side perspective view of an edge of the reflective member embodiment of FIG. 15.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

A solar concentrator assembly is disclosed. The solar concentrator assembly comprises a first reflective member comprising a first reflective surface, the first reflective member extending along a longitudinal axis and having a first end, wherein the first reflective surface extends to the first end of the first reflective member. The solar concentrator assembly also comprises a second reflective member comprising a second reflective surface, the second reflective member extending along the longitudinal axis and having a second end, wherein the second reflective surface extends to the second end of the second reflective member, the second reflective member positioned adjacent the first reflective member such that the first end of the first reflective member is adjacent the second end of the second reflective member. The solar concentrator assembly also comprises a photovoltaic receiver comprising at least one photovoltaic solar cell unit, the photovoltaic solar cell unit adapted to convert sunlight into electricity. Finally, the solar concentrator assembly also comprises a support structure coupled to the first and second reflective members and the photovoltaic receiver and adapted to position the photovoltaic receiver to receive reflected sunlight from at least the first reflective member.

In the solar concentrator assembly, the first reflective surface has a first edge along the first end and is shaped to concentrate sunlight in front of the first reflective member, and the first reflective surface has a concave shape. Additionally, the first reflective surface having a first edge region extending inward from the first edge, the first edge region formed in a shape which curves away from the photovoltaic receiver near the first edge. The second reflective surface has a second edge along the second end and is shaped to concentrate sunlight in front of the second reflective member, the second reflective surface also having a concave shape. The second reflective surface has a second edge region formed in a shape which curves away from the photovoltaic receiver in a region near the second edge.

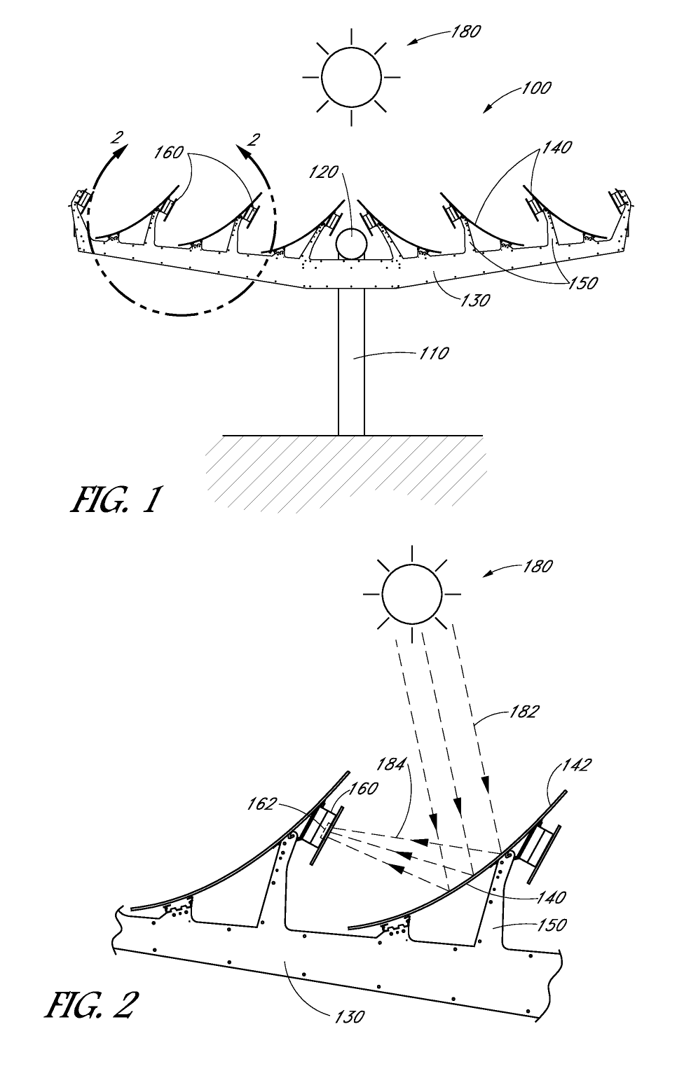

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically. Thus, although the schematic shown in, for example, FIGS. 1-3 depicts one exemplary arrangement of elements, additional intervening elements, devices, features, or components may be present in an embodiment of the depicted subject matter.

“Adjust”—Some elements, components, and/or features are described as being adjustable or adjusted. As used herein, unless expressly stated otherwise, “adjust” means to position, modify, alter, or dispose an element or component or portion thereof as suitable to the circumstance and embodiment. In certain cases, the element or component, or portion thereof, can remain in an unchanged position, state, and/or condition as a result of adjustment, if appropriate or desirable for the embodiment under the circumstances. In some cases, the element or component can be altered, changed, or modified to a new position, state, and/or condition as a result of adjustment, if appropriate or desired.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

FIG. 1 illustrates a view of a solar system 100 being irradiated by the sun 180. The solar system 100 is a concentrator system, although other solar systems can embody the features described. The solar system comprises a pier 110, a torque tube 120 supported by the pier 110, at least one cross beam 130 coupled to the torque tube 120, several solar concentrators or reflector elements 140 positioned and maintained by a support structure 150 which couples to one or more of the cross beams 130, and solar receivers 160. In some embodiments, the support structure 150 couples one of the solar receivers 160 to one or more of the cross beams 130. In some embodiments, one or more of the solar receivers 160 is coupled to the rear, non-reflective side of one or more solar concentrators 140. The torque tube 120 can rotate the assembled and positioned solar concentrators 140 and solar receivers 160 to track the sun during the day. By tracking the sun, the solar system 100 can receiver optimum irradiance during hours of sunlight.

The solar system 100 can adjust the position of the solar concentrators 140 to permit concentration of light from the sun 180 onto the solar receivers 160. The solar receivers 160 can be photovoltaic solar cells, or portions thereof, which convert the received sunlight into electrical current. Additional features can be incorporated into the solar system 100. For clarity and descriptive purposes, these are omitted. The support structure 150 can refer to one or more components coupling the solar concentrators 140 to the cross beam 130, the solar receivers 160 to the cross beam 130, the solar receivers 160 to the solar concentrators 140, or a combination thereof. For example, the support structure 150 can refer to all components coupling the pier 110 to the solar receiver 160, including the torque tube 120, the cross beam 130, and, in some embodiments, the solar concentrators 140. In other embodiments, the support structure 150 can refer to components which couple a solar receiver 160 to a solar concentrator 140, such as when a solar receiver 160 is mounted on the rear, non-reflective side of a solar concentrator 140. In still other embodiments, the support structure 150 can refer to components, members, or elements which couple a solar concentrator 140 to the cross beam 130. In still other embodiments, the support structure 150 can refer to components which couple a solar concentrator 140 to the torque tube 120 and can include one or several cross beams 130.

FIG. 2 illustrates a detailed view of a portion of the solar system 100 of FIG. 1. The solar concentrators 140 can have any of a number of shapes and sizes, such as the parabolic reflectors shown. The reflective surface 142 can receive unfocused sunlight 182 from the sun 180 and reflect and concentrate it into concentrated sunlight 184. The intensity of concentrated sunlight provided to a receiver, such as solar receiver 160, can be referred to by a measure of the intensity of illumination relative to unconcentrated sunlight. For example, a concentrator which provides concentrated sunlight which has twice the intensity of unconcentrated sunlight is said to provide two suns. The illustrated solar concentrator 140 can provide eleven suns of concentrated sunlight on a receiver embodiment, although the amount of concentration can vary between embodiments, from 2 to 50 suns. In certain embodiments, the solar system 100 can operate without a solar concentrator 140, and the solar receiver 160 can receive unconcentrated sunlight.

Preferably, the solar concentrator 140 directs the concentrated sunlight 184 to a predetermined location on the solar receiver 160. The solar receiver 160 includes a photovoltaic solar cell or a photovoltaic solar cell unit. The concentrated sunlight 184 preferably impinges on the solar cell 162 to enable electrical energy generation. The solar receiver 160 can include several components interoperating to produce electrical energy, such as interconnects connecting two or more photovoltaic solar cell units, an encapsulant, a carrier, a heat sink, and so on.

One face of the solar receiver 160 can be positioned to face toward the solar concentrator 140, receiving the concentrated sunlight 184. This face preferably includes the photovoltaic solar cell 162. It is desirable to position the solar system 100 such that the concentrated sunlight 184 reflected by the solar concentrator 140 impinges on the photovoltaic solar cell 162, and not other portions of the solar receiver 160, thereby increasing the electrical output of the solar cell 162 and, consequently, overall system efficiency. FIG. 2 illustrates a position where the concentrated sunlight 184 is appropriately directed.

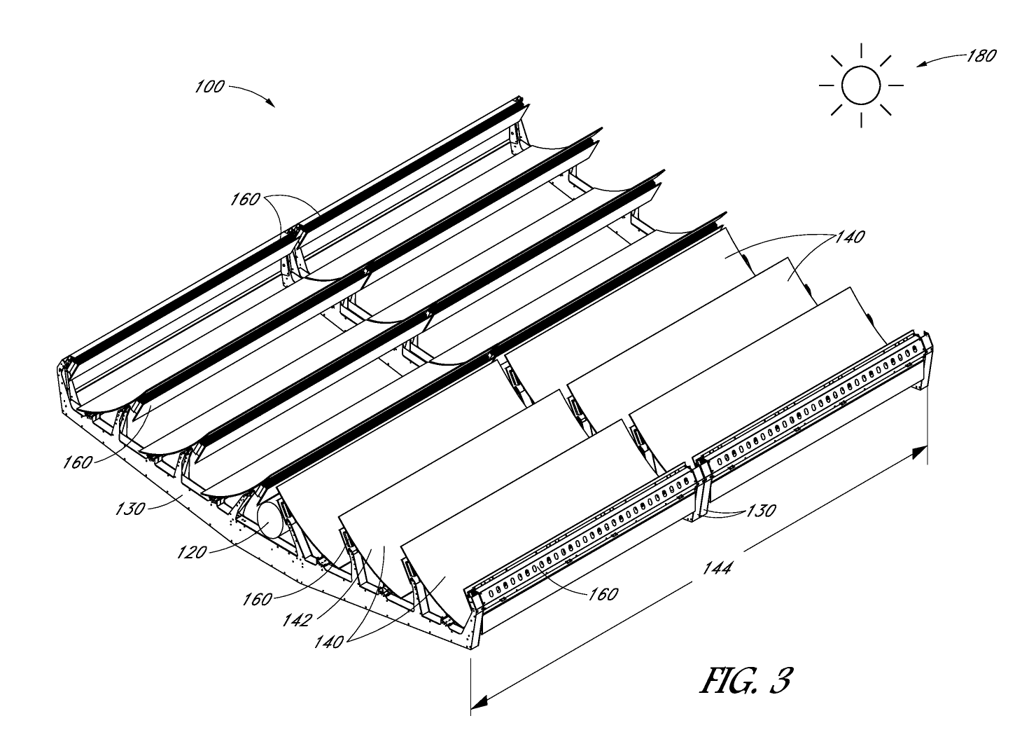

FIG. 3 illustrates a perspective view of the solar system 100. Several solar concentrators 140 can be arranged adjacent one another in the longitudinal axis or direction 144. In this way, the solar system 100 can extend along the longitudinal direction 144 and expand its area of capture for photovoltaic electrical conversion. In addition to the solar concentrators 140, solar receivers 160 can be arranged to correspond to the position of the solar concentrators 140. Thus, adjacent solar receivers 160 can extend along the longitudinal direction 144. Two or more adjacent sets of solar concentrators 140 with their corresponding solar receivers 160 can be present in an embodiment, increased to any desired number. For purposes of descriptive clarity, two such concentrators 140 and solar receivers 160 are shown in FIG. 3 and later Figures. Additionally, the illustrated embodiments, elements, and components are not illustrated to scale, but rather shown in a particular arrangement, position, or magnification for descriptive purposes.

FIG. 4 illustrates a view of two adjacent solar receivers 160a, 160b. The solar receivers 160a, 160b can be coupled to solar concentrators 140 or to one or more cross beams 130, in either case by directly or through an intermediary support structure 150. Each solar receiver 160a, 160b can include one or more solar cell units 162. The solar cell units 162 can be formed from a single silicon wafer, or a fragment or portion thereof. The solar cell units 162 can be front or back junction, front or back contact photovoltaic solar cell devices. In some embodiments, the solar cell units 162 can be composed of any desired device architecture, including CIGS, CdTe, polysilicon, and so on, without limitation. The solar receivers 160, 160a, 160b can include addition components and processes in its construction, including encapsulant material, a heat spreader and/or heat sink, an interconnect between adjacent solar cell units, one or more bypass diodes, thermocouples, and so on.

Each solar receiver 160a, 160b has an edge 166a, 166b near the other. The solar cell units 162 can extend up to the respective edges 166a, 166b of the solar receivers 160a, 160b, or can stop short. The edges 166a, 166b are separated by a receiver gap 168. The receiver gap 168 is preferably minimized, but as large as necessary to account for construction tolerances, thermal expansion of the solar receivers 160, cross beams 130, support structure 150, and other factors that benefit from a space between adjacent solar receivers 160.

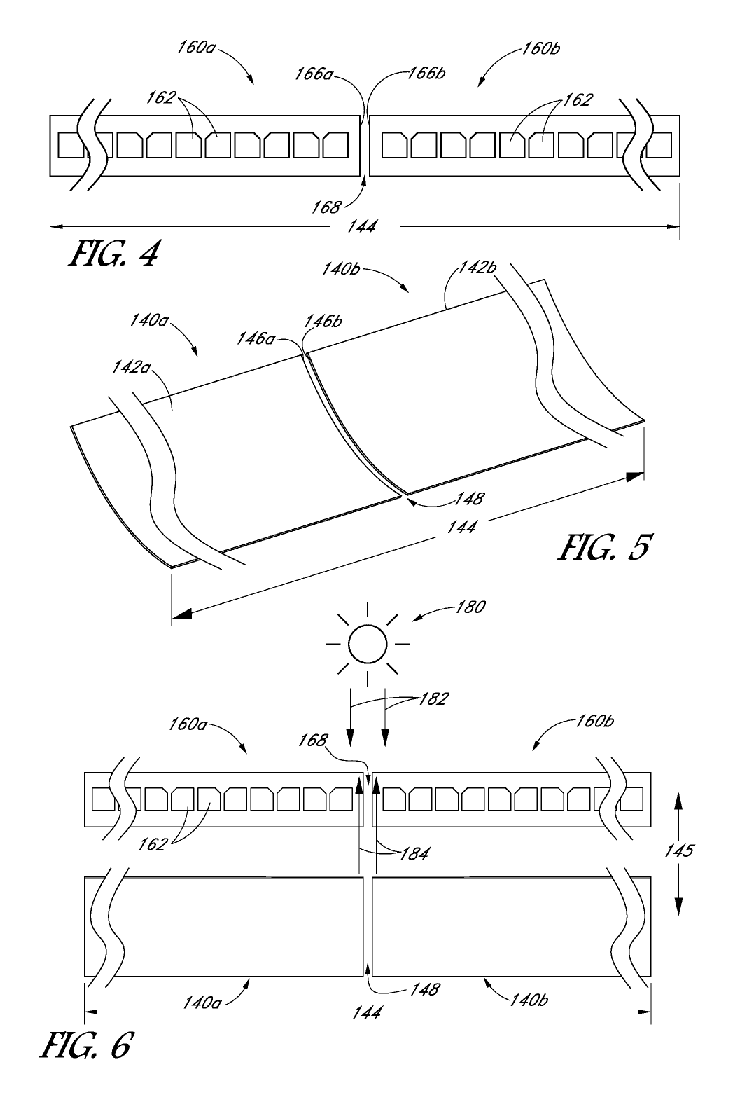

FIG. 5 illustrates a pair of adjacent solar concentrators 140a, 140b. The solar concentrators 140a, 140b can also be referred to as reflectors, mirrors, reflective members, reflector units, and so on. The solar concentrators 140a, 140b each have a reflective surface 142a, 142b. The reflective surfaces 142a, 142b can have a concave shape so as to focus sunlight on a solar receiver positioned in front of it. In some embodiments, the entire solar concentrator 140a, 140b can have a concave shape, not just the reflective surfaces 142a, 142b. The reflective surface 142 of any solar concentrator 140 can be on the inner surface of the concave reflector, such as a reflective film on a contoured structure, or it can be behind the inner surface, such as a silver or silvered layer on the rear side of a glass pane. In some embodiments, the solar concentrators 140 can be releasably coupled to the cross beams 130 or support structure 150, as described in greater detail in the U.S. Patent Applications with application Ser. Nos. 12/977,001 and 12/977,006, each of which is expressly incorporated herein by reference.

Each of the solar concentrators 140a, 140b has a respective edge 146a, 146b near the other solar concentrator 140b, 140a. Each concentrator 140a, 140b has another edge on the opposite side along the longitudinal direction 144 which is omitted for clarity. The edges 146a, 146b are separated in the longitudinal direction 144 by a concentrator gap 148. Each solar concentrator 140 is spaced apart from adjacent concentrators by concentrator gaps 148 between the edges 146 of the two concentrators. The end solar concentrators along each row do not have concentrator gaps on the outside of each end in a row.

The concentrator gap 148 can be designed to accommodate considerations similar to those of the receiver gap 168, including thermal expansion and construction tolerances, among others. The concentrator gap 148 can be aligned with the receiver gap 168, and each can be less than 30 mm, such as 3 mm, 8 mm, any fraction thereof, or any other designed amount. As shown in FIG. 6, which is a rear view of the concentrators 140a, 140b and receivers 160a, 160b. Other components of the solar system 100 are omitted for clarity.

Unconcentrated sunlight 182 is reflected by the solar concentrators 140a, 140b as concentrated sunlight 184. In the vertical direction 145, which is transverse to the longitudinal direction 144, the concentrated sunlight 184 can be concentrated and directed so as to impinge on the solar cell units 162. The true vertical direction, that is, the direction along the force of gravity experienced by the solar system 100, can be different than the vertical direction 145, which can be in-plane with the receiving face of a solar receiver 160a, 160b for purposes of description only.

As can be seen in FIG. 6, when the sun 180 is directly overhead, the concentrated sunlight 184 omitted from reflection because it impinges on the concentrator gap 148 is aligned with the receiver gap 168. Accordingly, there is effectively no lost concentrated sunlight 184 because all sunlight impinging on a solar concentrator 140 is reflected toward its corresponding solar receiver 160. The concentrator gap 148 does cause a gap in reflected sunlight 184 in the longitudinal direction 144, but because there is a corresponding receiver gap 160, there is no opportunity to convert the sunlight into electricity, and although the overall output of the solar system 100 is diminished slightly by the gaps 148, 168, all, or nearly all, of the reflected sunlight 184 is focused on the solar receivers 160.

The solar receivers 160 shown in FIG. 6 illustrate a convention of description. Each solar receiver 160 is said to be positioned in front of the solar concentrator 140 from which it receives concentrated sunlight 184. In some cases, as described herein, a solar receiver 160 can receive sunlight from another solar concentrator 140 as well, but for purposes of description, solar receiver 160a is in front of solar concentrator 140a and solar receiver 160b is in front of solar concentrator 140b. In some embodiments, the solar receivers 160 are coupled to the rear side of another solar concentrator 140. In some embodiments, the solar receivers 160 are coupled to a support structure 150 and/or one or more cross beams 130 because they are edge receivers. That is, they are the receivers furthest outward from the torque tube 120 as measured in a direction transverse to the longitudinal direction 144. No matter which solar receivers 160 in which position in the solar system 100 are being used as exemplary for purposes of description, the features described can be present in any of them.

FIG. 6 illustrates a situation where the sun 180 is directly overhead. In practice, this situation only occurs at select latitudes, varying by the seasons due to movement of the subsolar point. The subsolar point identifies the place on earth where the sun is perceived to be directly overhead. For example, during the December solstice, the subsolar point is on the Tropic of Capricorn. Similarly, during the June solstice, the subsolar point is on the Tropic of Cancer. During the equinoxes, the subsolar point is on the equator. In latitudes north of the Tropic of Cancer, the sun is perceived to always be in the southern half of the sky. Similarly, in latitudes south of the Tropic of Capricorn, the sun is perceived to always be in the northern half of the sky. Additionally, between the tropics, the sun appears to move between the northern and southern halves of the sky during the seasons. Illustrated and described herein is an improved solar system with reference made to the sun's apparent motion from an observer or solar system in the northern hemisphere with the sun in the southern half of the sky. Thus, this corresponds to any latitude north of the Tropic of Cancer or to latitudes between the Tropic of Cancer and the equator north of the subsolar point. With respect to systems positioned at other latitudes, the net effects described remain the same, while the direction is reversed. Additionally, all solar systems 100, 200, etc shown are arranged such that the torque tube is substantially north-south along its length. Some variations can also be used without deviating from the improvements described herein.

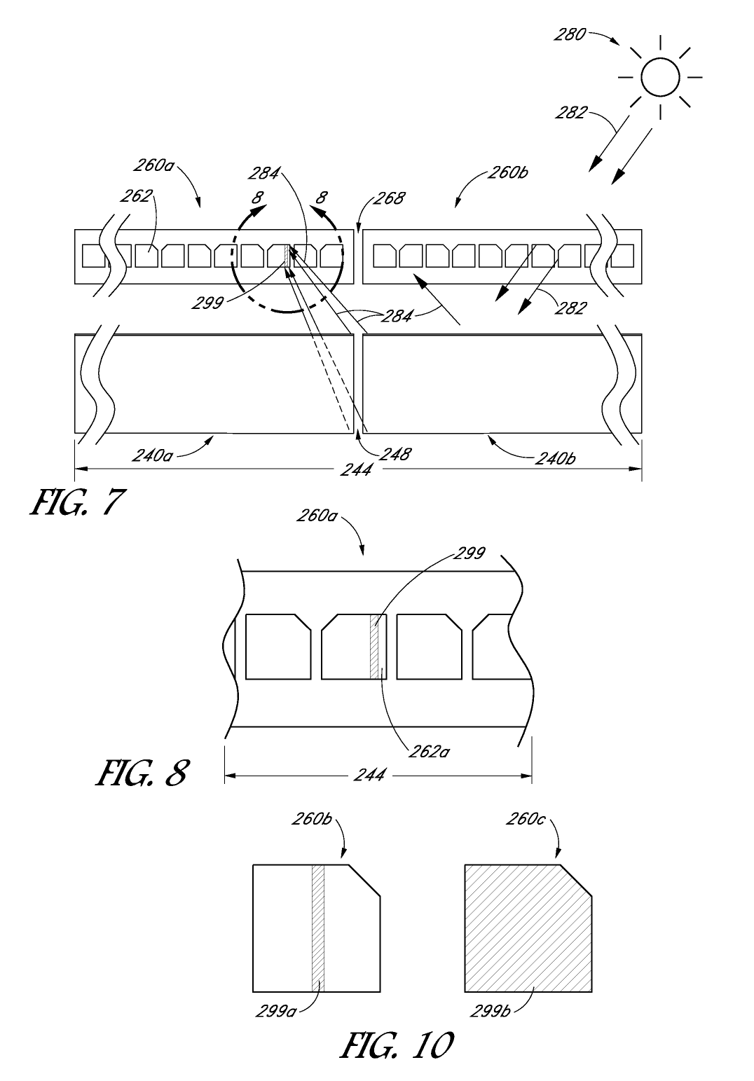

FIG. 7 illustrates a portion of the solar system embodiment 200. Unless otherwise designated, the components of FIGS. 7-10 are similar to those described above with reference to FIGS. 1-6, except that they have been incremented by 100.

The sun 280 is shown offset to the south from directly overhead. Thus, unconcentrated sunlight 282 impinges on the solar concentrators 240a, 240b at an angle. Accordingly, the concentrator gap 248 permits some unconcentrated sunlight 282 to exit the concentrator area without reflecting or concentrating it toward the solar receivers 260a, 260b. This lost unconcentrated sunlight 282 is manifest on the northern solar receiver 260a as a shadow region 299. The shadow region 299 will move north and south along the longitudinal direction 244 during the year as the subsolar point moves north and south. The shape of the shadow region 299, though depicted as a rectangular region with clean borders, can have variation, including variations in size and shape caused by seasonal movement of the sun, or insignificant imperfections in the concentrators' edges.

Because of this angle unconcentrated sunlight approaches from, the solar system can have one or more solar concentrator or one or more portions of a solar concentrator extending further to the south than the farthest southern extent of a solar receiver. This enables the solar system to capture all available sunlight, including that moved off-center by the motion of the earth and apparent motion of the sun.

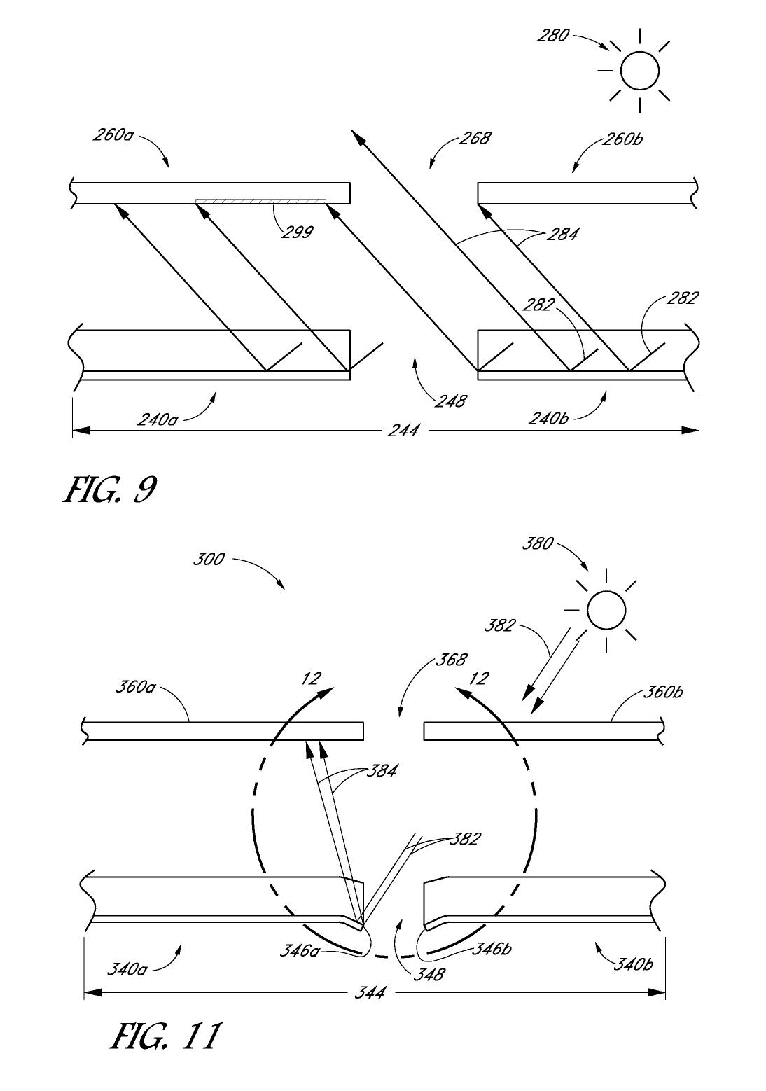

FIG. 8 illustrates a detailed view of the solar receiver 260a with an affected solar cell unit 262a. The shadow region 299 is formed by a gap in concentrated sunlight 284 caused by the concentrator gap 246 between the corresponding solar concentrator and the solar concentrator to the south of it. The shadow region 299 is not completely devoid of incoming impinging sunlight, but it is substantially less than the concentrated sunlight 284 in the regions to either side of it along the longitudinal direction 244. Thus solar cell units adjacent to the affected solar cell unit 262a are receiving reflected or concentrated sunlight 284 across all or substantially all of them, while the affected solar cell unit 262a has the shadow region 299. The shadow region 299 can be less than one sun, while immediately beside it, the affected solar cell unit 262a can be receiving the desired concentrated sunlight 284, of 6 suns, 7 suns, or any other desired amount. FIG. 9 illustrates a detailed top view of the area of interest.

FIG. 10 illustrates first and second solar cell units 260b, 260c. The illustrated solar cell units 260b, 260c are quarter-cell units although, as described above, other solar cell units can be formed from different configurations or embodiments. Solar cell unit 260b is illustrated with a shadow region 299a, and solar cell unit 260b is illustrated as having shadowed area 299b. The shadow region 299a causes a lack of photovoltaic current to be generated in solar cell unit 260b, but because it is isolated and restricted to a distinct region of the solar cell unit, the shadow region 299a is disproportionately impacting the solar cell unit. By way of explanation, solar cell unit 260c is shown with a shadowed area 299b. If the total sunlight impinging on both solar cell units 260b, 260c is the same, but the shaded area is restricted to shadow region 299a with respect to 260b, while it is evenly spread over the entire shadowed area 299b of solar cell unit 260c, the two solar cell units will produce different amounts of electricity, all other things being equal. Solar cell unit 260c will produce more electricity than solar cell unit 260b. This is because even though the total sunlight impinging on both is the same, the disproportionately deleterious effect of the concentrated shadow region 299a affects solar cell unit 260b more than the spread shadowed area 299b of solar cell unit 260c.

In both solar cell units 260b, 260c, lack of sunlight can cause a hot spot and the potential for current to be generated with a reverse polarity in the shaded area. The reverse polarity is measured relative to the direction of voltage during normal irradiated operation of the solar cell unit. Thus, the reverse bias condition can be formed in solar cell unit 260b, caused by the isolated shadow region 299a. Because the same lack of intensity of sunlight is evenly distributed over the entire shadowed area of solar cell unit 260c, while the current produced is decreased, no hot spot or reverse bias area develops in the cell. It is therefore desirable to spread the shadow region 299 out as evenly as possible.

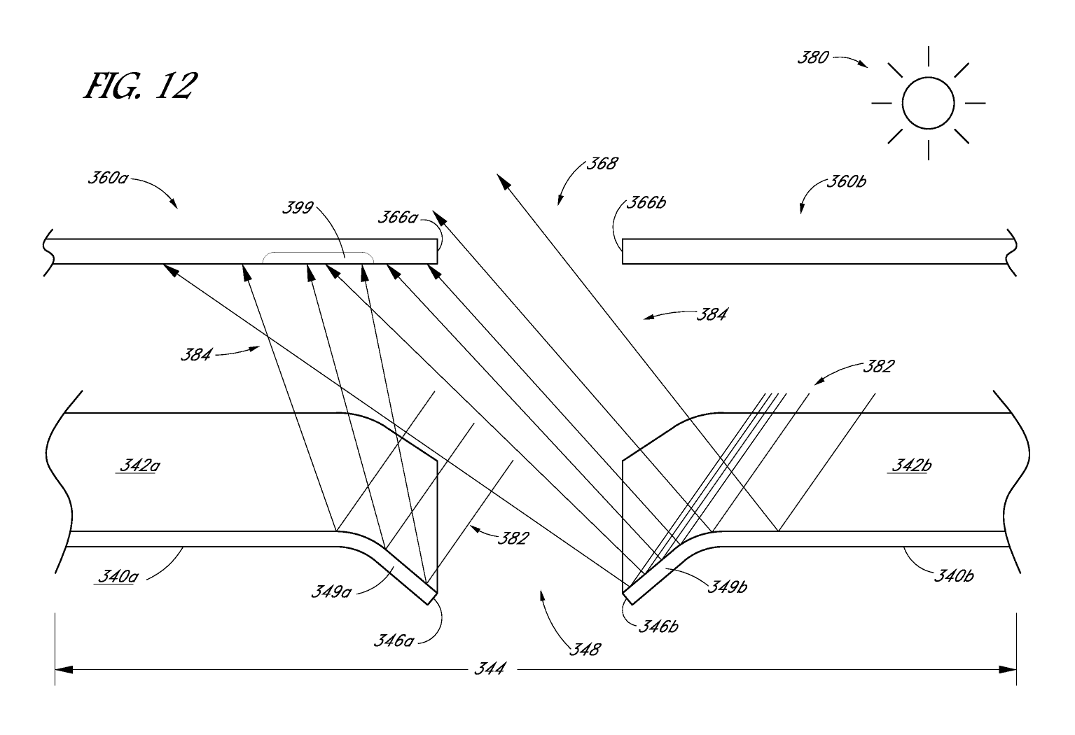

FIG. 11 illustrates a top view of a portion of a solar system 300. Unless otherwise described, the components of solar system 300 shown in FIGS. 11-13 are similar to those shown above with respect to solar system 200, except that the numerical indicators have been incremented by 100. Thus, some components of the solar system 300 have been omitted for clarity.

The inventors have discovered that edge design of the solar concentrators 340a, 340b can eliminate or minimize formation of the shadow region 399. FIG. 12 shows a detailed view of the indicated portion of FIG. 11.

Each edge 346a, 346b of the respective solar concentrator 340a, 340b can have an edge region 349a, 349b formed at an angle to the remainder of the solar concentrator 340a, 340b. Each edge region 349a, 349b can extend along substantially the entirety of the edge 346a, 346b on which it is situated, along the entire concave shape of the contour of the solar concentrator 340a, 340b. The edge regions 349a, 349b can be continuous with the remainder of the solar concentrators 340a, 340b, and the reflective surfaces 342a, 342b can be curved to continue onto the edge regions 349a, 349b.

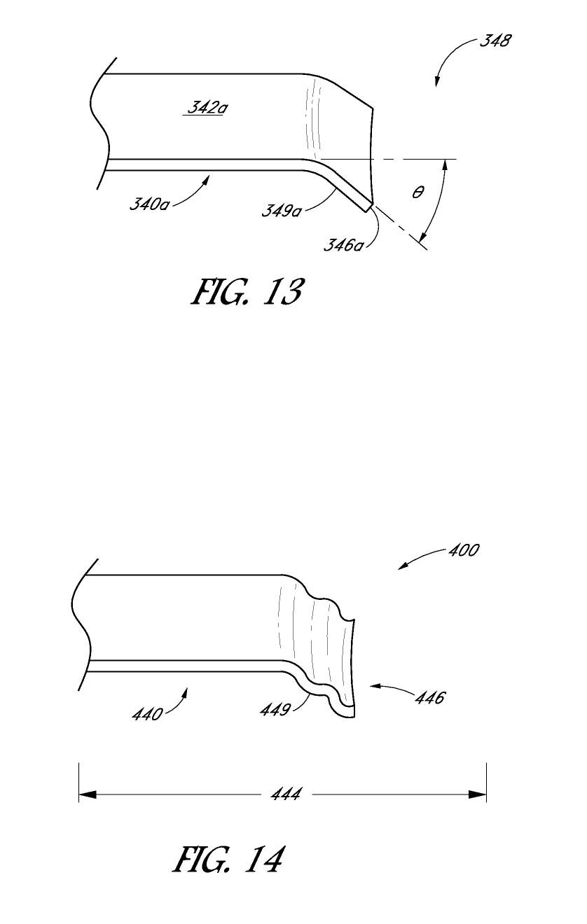

With additional reference to FIG. 13, the edge region 349a is shown with its angle θ measured against the remainder of the solar concentrator's 340a inner reflective surface 342a. Angle θ can be less than 10 degrees. In some embodiments, angle θ can be as little as 0.1 degrees. The edge region 349 itself can be measured as extending inward from the outer edge 346a of the solar concentrator 340a. The edge region 349 can extend inwardly from the edge 346a by a length of 10 mm, 15 mm, 20 mm, 75 mm, 3 mm, or any other distance desired for an embodiment. Any combination of distance and angle can be selected for an embodiment as desired. Additionally, and without limitation, it should be noted that the edge regions 349a, 349b both angle away from the solar receivers 360a, 360b.

Although illustrated on the edge 346a of solar concentrator 340a for descriptive purposes, it should be understood that, as shown in FIG. 12, both solar concentrators 340a, 340b can have edge regions 349a, 349b. Similarly, both edges of the solar concentrators 340a, 340b can have edge regions shaped and similar to edge regions 349a, 349b. Put another way, each longitudinally-extending solar concentrator has two ends. The edges at either end of a solar concentrator can have an edge region shaped as described.

Moreover, each such shaped edge region can include the reflective component or surface of the solar concentrator. Thus, for those embodiments where the reflective surface of a solar concentrator is a reflective film situated on a contoured surface, the reflective film can extend around the angle and onto the edge region. For those embodiments where the solar concentrator comprises a mirror with a glass inner surface and a reflective surface behind the glass inner surface, both the glass surface and reflective surface can be angled as described for the desired length.

With reference again to FIG. 12, the edge regions 349a, 349b can angle the reflected sunlight 384 in a spread toward the former shadowed region, indicated as 399. The edge region 349b can bend away from the relative position of the sun 380, causing the reflected sunlight 384 near the concentrator gap 348 to be reflected further north along the longitudinal direction 344 than in those embodiments without shaped edge regions. In a complementary manner, reflected sunlight 384 from the first edge region 349a is reflected further southward along the longitudinal direction 344 than in an embodiment without shaped edge regions. The combined effect of both edge regions 349a, 349b is to direct some sunlight toward what was formerly the shadow region, indicated by 399. The reflected sunlight 384 which reflects from the edge regions 349a, 349b impinges on the solar receiver 360a formerly, in an embodiment without edge regions, would have impinged in an area other than the former shadow region 399. Accordingly, the total amount of sunlight impinging on the solar receiver 360 is not increased. The effect of a shadow region is, however, reduced.

In certain embodiments, the former shadow region, now 399, can receive less sunlight than surrounding regions of the solar receiver 360a. In some embodiments, the solar receiver 360a can have no region experiencing less than 1.1 suns of sunlight reflected from the solar concentrators 340a, 340b. Thus, the former shadow region, indicated by 399, may previously have been irradiated by as little as 0.5 suns of sunlight caused by the concentrator gap. Accordingly, the edge regions 349 can minimize or eliminate hot spots along the solar receivers, improving overall system performance even though the amounts of both concentrated and unconcentrated sunlight is constant.

FIG. 14 illustrates an alternative embodiment of an edge region 449. Unless otherwise described, the components of solar system 400 shown in FIG. 14 are similar to those shown above with respect to solar system 300, except that the numerical indicators have been incremented by 100. Thus, some components of the solar system 400 have been omitted for clarity.

The edge region 449 can have one or more surface topological features in the reflective surface. As shown, the edge region 449 can have a curve extending outwardly, a curve extending inwardly, or a combination of the two in the same embodiment. These undulations can be said to extend in the longitudinal direction 444. The features shown are relative to a flat concentrator surface. For a concave concentrator, the features shown would extend in three dimensions and can, for example, incorporate or include undulations or topological features along the edge of the concave concentrator.

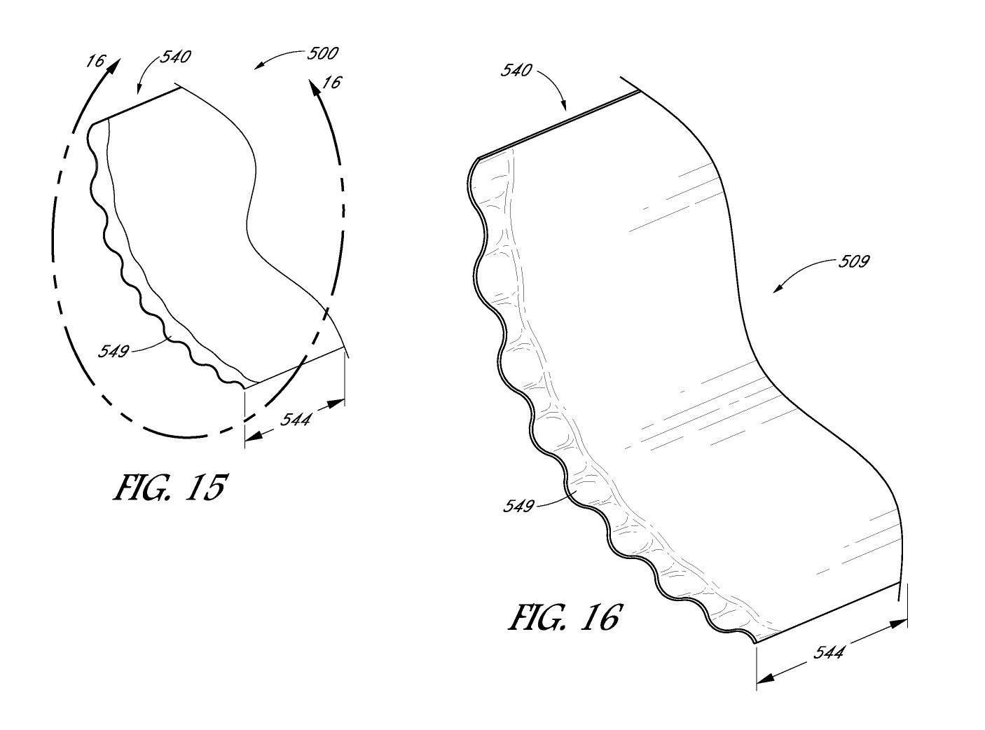

FIGS. 15 and 16 illustrate one embodiment with undulations along the edge of the concentrator. Unless otherwise described, the components of solar system 500 shown in FIGS. 11-13 are similar to those shown above with respect to solar system 300, except that the numerical indicators have been incremented by 200. Thus, some components of the solar system 500 have been omitted for clarity.

FIG. 15 illustrates the edge of a solar concentrator 540 with an edge having a topologically-varying surface including undulations or waves in one or more directions, including directions transverse to the longitudinal direction 544. FIG. 16 illustrates a detailed view of the edge of solar concentrator 540 having edge region 549. The edge region 549 can have undulations as viewed from the edge-on, indicating variations along the concave shape. In some embodiments, the undulations can extend exclusively or additionally in the transverse direction, namely, along the longitudinal direction. In some embodiments, the edge region 549 is not angled, i.e., θ is equal to zero. In such embodiments, the surface topology—whether undulations, concave portions, convex portions, or any other type or reflecting variance from the remainder of the solar concentrator 540 can be sufficient to achieve the same effect of reducing or eliminating the concentrated shadow region without the bend. Any combination of these or other features is also possible, as desired for an embodiment.

No embodiment is intended to be exclusive of any features disclosed with reference to any other embodiment. Thus, for example, as the size and angle of the edge regions can vary between embodiments, so too surface features in the edge regions can vary and be incorporated with any combination of other features. Thus, an edge region can have undulations in the longitudinal direction as well as up and down along its contoured edge. Similarly, in some embodiments, the edge regions can have a relatively small angle θ of only 0.1 or 0.25 degrees, undulations only up and down the contoured edge, and extend inward only 2 mm from the edge of the solar concentrator. In other embodiments, the edge region can have a relatively large angle θ of 8 degrees, extend inwardly 15 mm from the edge of the solar concentrator, and have no undulations or other topological features. Any other combination of feature selections can also be used in an embodiment as desired.

Thus, while at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A solar concentrator assembly comprising:
a first reflective member comprising a first reflective surface, the first reflective member extending along a longitudinal axis and having a first end, wherein the first reflective surface extends to the first end of the first reflective member;
a second reflective member comprising a second reflective surface, the second reflective member extending along the longitudinal axis and having a second end, wherein the second reflective surface extends to the second end of the second reflective member, the second reflective member positioned adjacent the first reflective member such that the first end of the first reflective member is adjacent the second end of the second reflective member;
a photovoltaic receiver comprising at least one photovoltaic solar cell unit, the photovoltaic solar cell unit adapted to convert sunlight into electricity; and
a support structure coupled to the first and second reflective members and the photovoltaic receiver and adapted to position the photovoltaic receiver to receive reflected sunlight from at least the first reflective member, wherein:
the first reflective surface has a first edge along the first end and is shaped to concentrate sunlight in front of the first reflective member, the first reflective surface having a concave shape;
the first reflective surface having a first edge region extending inward from the first edge, the first edge region formed in a shape which curves away from the photovoltaic receiver near the first edge;
the second reflective surface has a second edge along the second end and is shaped to concentrate sunlight in front of the second reflective member, the second reflective surface having a concave shape; and
the second reflective surface having a second edge region formed in a shape which curves away from the photovoltaic receiver in a region near the second edge.

2. The solar concentrator assembly of claim 1, wherein the first edge region is shaped to reflect sunlight toward the second reflective member.

3. The solar concentrator assembly of claim 1, wherein the second edge region is shaped to reflect sunlight toward the first reflective member.

4. The solar concentrator assembly of claim 1, wherein the first and second reflective members are sized and shaped to focus concentrated sunlight on the photovoltaic receiver.

5. The solar concentrator assembly of claim 4, wherein the reflected sunlight received by the photovoltaic receiver is concentrated sunlight which is concentrated to between 2 and 20 times the intensity of unconcentrated sunlight.

6. The solar concentrator assembly of claim 1, wherein the first edge region is formed at an angle of less than five degrees from the remainder of the first reflective surface.

7. The solar concentrator assembly of claim 6, wherein the second edge region is formed at an angle of less than five degrees from the remainder of the second reflective surface, the angled surface in the direction of the first reflective member.

8. The solar concentrator assembly of claim 1, wherein the first edge region has a cross-sectional shape similar to the remainder of the first reflective surface.

9. The solar concentrator assembly of claim 1, wherein the first edge region has an undulating cross-sectional shape.

10. The solar concentrator assembly of claim 9, wherein the undulations extend in a direction along the longitudinal axis.

11. The solar concentrator assembly of claim 9, wherein the undulations extend in a direction transverse to the longitudinal axis.

12. The solar concentrator assembly of claim 11, wherein the undulations extend along the concave edge of the first reflective surface.

13. The solar concentrator assembly of claim 1, wherein the first and second reflective members are separated by a gap of less than 5.0 millimeters.

14. The solar concentrator assembly of claim 1, wherein the first edge region extends inward from the first edge less than 50 millimeters.

15. The solar concentrator assembly of claim 14, wherein the second edge region extends inward from the second edge less than 50 millimeters.

16. The solar concentrator assembly of claim 1, further comprising a second photovoltaic receiver, wherein:
the second photovoltaic receiver comprises at least one photovoltaic solar cell unit;
the support structure is further adapted to position the second photovoltaic receiver to receive reflected sunlight from at least the first second reflective member; and
wherein the second photovoltaic receiver is positioned in front of the second reflective member.

17. The solar concentrator assembly of claim 16, wherein the second reflective member has a third edge along a third end opposite the second end, and the second reflective surface has a third edge region formed in a shape which curves away from the second photovoltaic receiver in a region near the third edge.

18. The solar concentrator assembly of claim 1, wherein the photovoltaic receiver is positioned in front of the first reflective member.

19. The solar concentrator assembly of claim 1, wherein the photovoltaic solar cell unit comprises a fraction of a single-cell unit.

20. The solar concentrator assembly of claim 19, wherein the photovoltaic solar cell unit comprises a back-contact photovoltaic solar cell.
